(19) United States
(12) Patent Application Publication
(10) Pub. No.: US 2016/0118244 A1
(43) Pub. Date: Apr. 28, 2016

(54) THIN FILM TRANSISTOR ELEMENT, PRODUCTION METHOD FOR SAME, AND DISPLAY DEVICE

(71) Applicant: JOLED INC., Chiyoda-ku, Tokyo (JP)

(72) Inventors: Hiroshi HAYASHI, Tokyo (JP); Yoshiaki NAKAZAKI, Tokyo (JP); Yuji KISHIDA, Tokyo (JP)

(73) Assignee: JOLED INC., Tokyo (JP)

(21) Appl. No.: 14/895,545

(22) PCT Filed: Feb. 27, 2014
(86) PCT No.: PCT/JP2014/001043

§ 371 Date: Dec. 3, 2015

(30) Foreign Application Priority Data
Jun. 4, 2013 (JP) 2013-117990

(51) Int. Cl. H01L 21/02; H01L 27/12; H01L 29/66; H01L 29/786; H01L 29/423

(52) U.S. Cl. CPC H01L 21/02252; H01L 29/7869; H01L 29/42384; H01L 29/66969; H01L 21/02274; H01L 21/0214; H01L 27/1225

(57) ABSTRACT

A thin-film transistor includes: a gate electrode; a source electrode; a drain electrode; a channel layer that is in contact with the source electrode and the drain electrode, and includes oxide semiconductor; and a gate insulating layer that is disposed between the gate electrode and the channel layer, and is in contact with the gate electrode and the channel layer, wherein a region of the gate insulating layer that is in contact with the channel layer is a silicon compound film, and the silicon compound film contains silicon, nitrogen, and oxygen, and is formed by performing plasma processing for introducing, into a film containing silicon and one of nitrogen and oxygen, the other of nitrogen and oxygen.

### TECHNICAL FIELD

The present disclosure relates to a thin-film transistor (TFT), a manufacturing method thereof, and a display device including the TFT. The present disclosure relates particularly to an art of improving reliability of a TFT including a channel layer including oxide semiconductor.

### BACKGROUND ART

In liquid crystal display devices and organic electroluminescence (EL) display devices of an active matrix driving type, TFTs are broadly used as drive elements of subpixels.

In recent years, research and development have been actively conducted on TFTs including a channel layer of oxide semiconductor. Such oxide semiconductor has a reduced off-current and a high electron mobility even in an amorphous state, and is also formed through a process at a low temperature. Examples of oxide semiconductor include zinc oxide (ZnO), indium gallium oxide (InGaO), and indium gallium zinc oxide (InGaZnO).

With respect to the TFTs including the channel layer of oxide semiconductor, there has been known that a threshold voltage tends to shift due to stress such as current application. The threshold voltage means a gate-source voltage that turns on the TFTs. Time-dependent threshold voltage shift of the TFTs influences luminance control on a display device, and deteriorates the display quality.

One of commonly known causes for the time-dependent threshold voltage shift is that defects, which exist in a gate insulating layer that is adjacent to the channel layer, trap carriers in the channel layer. The defects occur in the gate insulating layer mainly during a manufacturing process of TFTs. For example, as shown in FIG. 15, in formation of a channel layer after formation of a gate insulating layer 9013, when high-energy ions collide with a surface of the gate insulating layer 9013, defects occur in the surface of the gate insulating layer 9013.

Here, as a method of suppressing occurrence of defects in a gate insulating layer, there has been employed an art of forming the gate insulating layer from a silicon oxynitride film that is more dense than a commonly-used silicon oxide film. Further, there has been known, as a method of forming a silicon oxynitride film, a method of directly forming a silicon oxynitride film by a chemical vapor deposition (CVD) method (see for example Patent Literature 1). Moreover, there has been known a method of forming a silicon oxide film, and implanting nitrogen into the silicon oxide film by an ion implantation method to form a silicon oxynitride film as a surface of the silicon oxide film (see for example Patent Literature 2).

### CITATION LIST

### Patent Literature

[Patent Literature 1] Japanese Patent Application Publication No. H06-318703

[Patent Literature 2] Japanese Patent Application Publication No. H07-86593

### Non-Patent Literature

[Non-Patent Literature 1] J. Lee et. al., Appl. Phys. Lett. 95, 123502 (2009)

### SUMMARY OF INVENTION

### Technical Problem

A silicon oxynitride film, which is formed by the CVD method such as disclosed in Patent Literature 1, has a high hydrogen concentration due to silane that is a source gas thereof. Time-dependent threshold voltage shift is caused by TFTs including a channel layer of oxide semiconductor and a gate insulating layer formed from such a silicon oxynitride film having a high hydrogen concentration (see Non-Patent Literature 1).

Also, a silicon oxynitride film, which is formed by the ion implantation method such as disclosed in Patent Literature 2, has defects caused by ion collision. In this case, since anneal processing is necessary in order to remove the defects, a problem occurs that material of a substrate of TFTs is limited to a highly heat-resistant one. Also, since the ion implantation method restricts an utilizable size of the substrate, a further problem occurs that manufacturing costs increase.

In view of the above problems, the present disclosure aims to provide a TFT, and a manufacturing method thereof, and a display device including the TFT according to which although a channel layer is formed from oxide semiconductor, time-dependent threshold voltage shift is reduced, there are fewer limitations on utilizable material and size of the substrate, and increase of manufacturing costs is suppressed.

### Solution to Problem

A thin-film transistor relating to one aspect of the present disclosure comprises: a gate electrode; a source electrode; a drain electrode; a channel layer that is in contact with the source electrode and the drain electrode, and includes oxide semiconductor; and a gate insulating layer that is disposed between the gate electrode and the channel layer, and is in contact with the gate electrode and the channel layer, wherein a region of the gate insulating layer that is in contact with the channel layer is a silicon compound film, and the silicon compound film contains silicon, nitrogen, and oxygen, and is formed by performing plasma processing for introducing, into a film containing silicon and one of nitrogen and oxygen, the other of nitrogen and oxygen.

### Advantageous Effects of Invention

The TFT relating to the above aspect includes, as the gate insulating layer, a silicon compound film having fewer defects and a less amount of contained hydrogen, which is formed by performing plasma processing. Therefore, in the TFT relating to the above aspect, although the channel layer includes oxide semiconductor, the threshold voltage shift is reduced, there are fewer limitations on the utilizable material and size of the substrate, and therefore increase of manufacturing costs is suppressed.

### BRIEF DESCRIPTION OF DRAWINGS

FIG. 1 is a schematic cross-sectional view showing a structure of a TFT 101.

FIGS. 2A-2C are schematic cross-sectional views showing a process of forming the TFT 101, specifically FIG. 2A shows a process of forming a gate electrode, FIG. 2B shows a process of forming a gate insulating layer, and FIG. 2C shows a process of performing plasma processing.

FIGS. 3A-3D are schematic cross-sectional views showing the process of forming the TFT 101, specifically FIGS. 3A and 3B show a process of forming a channel layer, FIG. 3C shows a process of forming a channel protection layer, and FIG. 3D shows a process of forming a source electrode and a drain electrode.

FIG. 4A is a schematic cross-sectional view showing a direction in which an SIMS profile was measured with respect to an example of the TFT 101, FIG. 4B is a graph showing an SIMS profile of nitrogen concentration, and FIG. 4C is a graph showing an SIMS profile of hydrogen concentration.

FIG. 5A is a schematic cross-sectional view showing a direction in which an SIMS profile was measured with respect to a comparative example, FIG. 5B is a graph showing an SIMS profile of nitrogen concentration, and FIG. 5C is a graph showing an SIMS profile of hydrogen concentration.

FIG. 6A is a graph showing behavior of threshold voltage shift with respect to the comparative example, FIG. 6B is a graph showing behavior of threshold voltage shift with respect to the example, and FIG. 6C is a graph showing behavior of threshold voltage shift with respect to the example.

FIGS. 7A-7C are schematic cross-sectional views showing a process of forming a TFT 301 relating to Embodiment 2, specifically FIG. 7A shows a process of forming a gate electrode, FIG. 7B shows a process of a gate insulating layer, and FIG. 7C shows a process of performing plasma processing.

FIGS. 8A-8C are schematic cross-sectional views showing the process of forming the TFT 301, specifically FIGS. 8A and 8B show a process of forming a channel layer, and FIG. 8C shows a process of forming a source electrode and a drain electrode.

FIGS. 9A-9D are schematic cross-sectional views showing a process of forming a TFT 401 relating to Embodiment 3, specifically FIG. 9A shows a process of forming a channel layer, FIG. 9B shows a process of forming an insulating layer, FIG. 9C shows a process of performing plasma processing, and FIG. 9D shows a process of forming a gate insulating layer.

FIGS. 10A-10C are schematic cross-sectional views showing the process of forming the TFT 401, specifically FIG. 10A shows a process of forming a gate electrode, FIG. 10B show a process of forming an interlayer insulating layer, and FIG. 10C shows a process of forming a source electrode and a drain electrode.

FIG. 11 is a schematic block view showing outline of a structure of an organic EL display device 1 relating to Embodiment 4.

FIG. 12 shows a circuit structure of a subpixel 10a.

FIG. 13 is a schematic cross-sectional view partially showing a structure of an organic EL display panel 10.

FIG. 14 is a schematic cross-sectional view showing a structure of a TFT 901 relating to a comparative example.

FIG. 15 is a schematic cross-sectional view showing a process of forming a channel layer relating to a conventional art.

### DESCRIPTION OF EMBODIMENTS

<Outline of One Aspect of the Present Disclosure>

A thin-film transistor relating to one aspect of the present disclosure comprises: a gate electrode; a source electrode; a drain electrode; a channel layer that is in contact with the source electrode and the drain electrode, and includes oxide semiconductor; and a gate insulating layer that is disposed between the gate electrode and the channel layer, and is in contact with the gate electrode and the channel layer, wherein a region of the gate insulating layer that is in contact with the channel layer is a silicon compound film, and the silicon compound film contains silicon, nitrogen, and oxygen, and is formed by performing plasma processing for introducing, into a film containing silicon and one of nitrogen and oxygen, the other of nitrogen and oxygen.

Also, in the thin-film transistor relating to another aspect of the present disclosure, the channel layer is disposed between the gate electrode and each of the source electrode and the drain electrode.

Also, in the thin-film transistor relating to yet another aspect of the present disclosure, the silicon compound film is a silicon oxynitride film resulting from performing plasma nitridation processing on a silicon oxide film or performing plasma oxidation processing on a silicon nitride film.

The TFT relating to the above aspect includes a silicon compound film having fewer defects and a less amount of contained hydrogen in the region of the gate insulating layer that is in contact with the channel layer. Therefore, in the TFT relating to the above aspect, although the channel layer includes oxide semiconductor, threshold voltage shift is reduced.

Also, in the TFT relating to the above aspect, since the gate insulating layer has fewer defects, anneal process may not need to be performed, and thus the substrate may not need to be formed from a highly heat-resistant material. Further, in the TFT relating to the above aspect, since the plasma processing is used, there are fewer limitations on the size of the substrate and therefore increase of manufacturing costs is suppressed, compared with the case where the ion implantation method is used.

Also, in the TFT relating to further another aspect of the present disclosure, the silicon compound film includes a layer having a nitrogen concentration of 2×10²⁰ cm⁻³ or higher, and the silicon compound film has a hydrogen concentration of 2×10²¹ cm⁻³ or less. In the TFT relating to the above aspect according to this structure, the gate insulating layer has sufficiently reduced defects and a sufficiently reduced amount of contained hydrogen. Accordingly, the time-dependent threshold voltage shift is reduced more certainly.

Also, in the TFT relating to another aspect of the present disclosure, the silicon compound film has a thickness of 6 nm to 30 nm. In the TFT relating to the above aspect according to this structure, most part of the region of the gate insulating layer in which carriers can be trapped is formed from a silicon compound film having fewer defects and a less amount of contained hydrogen. Also, this structure suppresses occurrence of defects in the silicon compound film due to excessive plasma processing. Accordingly, the time-dependent threshold voltage shift is reduced more effectively.

A display device relating to yet another aspect of the present disclosure comprises: the thin-film transistor of any of the above aspects; and a pixel part that is connected with the thin-film transistor. This structure allows the display device relating to the above aspect to have high capability and reliability, and suppresses increase of manufacturing costs.

A method of manufacturing a thin-film transistor relating to further another aspect of the present disclosure comprises: forming a gate electrode; forming a gate insulating layer on the gate electrode; forming a channel layer including oxide semiconductor on the gate insulating layer; and forming a source electrode and a drain electrode on the channel layer, wherein the gate insulating layer is formed by forming a first film containing silicon and one of nitrogen and oxygen, and performing plasma processing to introduce the other of nitrogen and oxygen into the first film, such that the gate insulating layer has a second film containing silicon, nitrogen, and oxygen as an upper surface thereof.

A method of manufacturing a thin-film transistor relating to another aspect of the present disclosure comprises: forming a channel layer including oxide semiconductor; forming a gate insulating layer on the channel layer; forming a gate electrode on the gate insulating layer; and forming a source electrode and a drain electrode on the channel layer, wherein the gate insulating layer is formed by forming a first film containing silicon and one of nitrogen and oxygen, and performing plasma processing to introduce the other of nitrogen and oxygen into the first film, such that the gate insulating layer has a second film containing silicon, nitrogen, and oxygen as a lower surface thereof.

In the method of manufacturing the thin-film transistor relating to yet another aspect of the present disclosure, as the first film, a silicon oxide film or a silicon nitride film is formed, and as the second film, a silicon oxynitride film is formed, the silicon oxynitride film resulting from performing plasma nitridation processing on the silicon oxide film or performing plasma oxidation processing on the silicon nitride film.

According to the manufacturing method relating to the above aspect, it is possible to form a silicon compound film having fewer defects and a less amount of contained hydrogen in the region of the gate insulating layer that is in contact with the channel layer. Therefore, although the channel layer includes oxide semiconductor, it is possible to manufacture the TFT with a reduced threshold voltage shift.

Further, according to the manufacturing method relating to the above aspect, the plasma processing is used for forming a silicon compound film. This reduces defects in the gate insulating layer without performing anneal process. Accordingly, the substrate may not need to be formed from a highly heat-resistant material. Also, compared with the case where the ion implantation method is used, there are fewer limitations on the size of the substrate, and therefore increase of manufacturing costs is suppressed.

The following explains characteristics and effects of an aspect relating to the present disclosure and effects with use of specific examples.

### Embodiment 1

The following explains, as one aspect of the present disclosure, a TFT 101 relating to Embodiment 1 that is a bottom gate TFT with a channel protection layer.

1. Cross-Sectional Structure of TFT 101

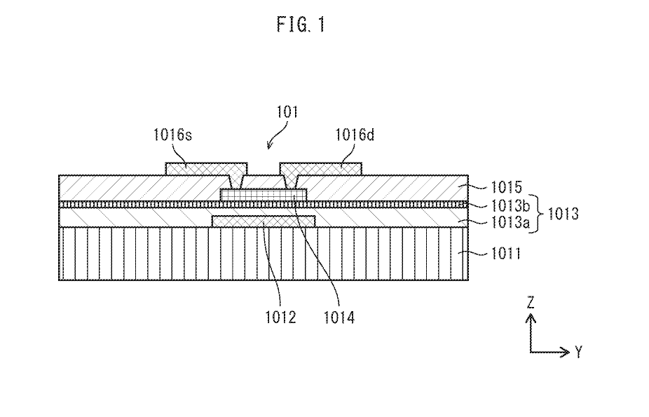

A cross-sectional structure of the TFT 101 is explained with reference to FIG. 1.

As shown in FIG. 1, in the TFT 101, a gate electrode 1012 is formed on a substrate 1011, and a gate insulating layer 1013 is formed on the substrate 1011 so as to cover the gate electrode 1012.

Here, the gate insulating layer 1013 includes a first gate insulating layer 1013a and a second gate insulating layer 1013b. The first gate insulating layer 1013a is formed on the substrate 1011 so as to cover the gate electrode 1012, as a layer that is positioned lower in a Z-axis direction (positioned on the side of a lower surface) of the gate insulating layer 1013. The second gate insulating layer 1013b is formed on the first gate insulating layer 1013a, as a layer that is positioned upper in the Z-axis direction (positioned on the side of an upper surface) of the gate insulating layer 1013.

Also, a channel layer 1014 is formed on the gate insulating layer 1013 so as to correspond in position to the gate electrode 1012. Further, a channel protection layer 1015 is formed on the gate insulating layer 1013 so as to cover the channel layer 1014. Note that the channel layer 1014 and the channel protection layer 1015 are formed on the second gate insulating layer 1013b.

Moreover, a source electrode 1016s and a drain electrode 1016d are formed on the channel protection layer 1015 with an interval therebetween. The source electrode 1016s and the drain electrode 1016d are also each formed in a contact hole that is formed in part of the channel protection layer 1015, which is positioned on the channel layer 1014, and are connected with the channel layer 1014.

2. Materials of TFT 101

Compositional elements of the TFT 101 are formed for example from materials as shown below.

(1) Substrate 1011

The substrate 1011 is formed from an insulating material. The substrate 1011 is formed for example from glass material such as non-alkali glass, quartz glass, and highly heat-resistant glass, resin material such as polyimide, semiconductor material such as silicon, metal material such as stainless coated with an insulating layer, or the like.

(2) Gate Electrode 1012

Material of the gate electrode 1012 is not specifically limited as long as the material is conductive. The gate electrode 1012 is formed for example from metal such as molybdenum (Mo), aluminum, copper (Cu), tungsten (W), titanium, manganese, and chrome, alloy such as molybdenum-tungsten, light-transmissive conductive material such as indium tin oxide (ITO), aluminum-doped zinc oxide (AZO), and gallium-doped zinc oxide (GZO), or the like. Alternatively, the gate electrode 1012 may have a multi-layer structure including these above materials.

(3) Gate Insulating Layer 1013

The gate insulating layer 1013 has a multi-layer structure including the first gate insulating layer 1013a and the second gate insulating layer 1013b, as described above. The first gate insulating layer 1013a has insulating properties, and includes material that can be precursor of the second gate insulating layer 1013b. The material should preferably have a less amount of contained hydrogen. The first gate insulating layer 1013a for example has a single-layer structure or a multi-layer structure including a silicon oxide film, which contains oxygen and thereby has an interface in an excellent state with oxide semiconductor, and/or a silicon nitride film, which is dense and has a high permittivity. Alternatively, the gate insulating layer 1013 may have a multi-layer structure including these films and at least one of a silicon oxide film, a silicon oxynitride film, an aluminum oxide film, a tantalum oxide film, and a hafnium oxide film.

In the case where the first gate insulating layer 1013a has a multi-layer structure, the gate insulating layer 1013a needs to include a layer formed from material that can be precursor of the second gate insulating layer 1013b as an uppermost layer thereof in the Z-axis direction in FIG. 1.

The second gate insulating layer 1013b is formed from material that has a dense structure and thereby is highly resistant to collision with high-energy ions, and has an interface in an excellent state with oxide semiconductor. For example, the second gate insulating layer 1013b is formed from a silicon oxynitride film.

(4) Channel Layer 1014

The channel layer 1014 is formed from oxide semiconductor containing at least one of indium (In), gallium (Ga), and zinc (Zn). For example, the channel layer 1014 is formed from amorphous indium gallium zinc oxide (InGaZnO).

(5) Channel Protection Layer 1015

The channel protection layer 1015 is formed from insulating material that protects the channel layer 1014 against damages during etching. The channel protection layer 1015 for example has a single-layer structure or a multi-layer structure including a film formed from inorganic material such as a silicon oxide film, a silicon nitride film, a silicon oxynitride film, and an aluminum oxide film and/or a film mainly formed from organic material containing silicon, oxygen, and carbon.

(6) Source Electrode 1016s and Drain Electrode 1016d

The source electrode 1016s and the drain electrode 1016d are formed for example from the same material as the gate electrode 1012.

3. Manufacturing Method of TFT 101

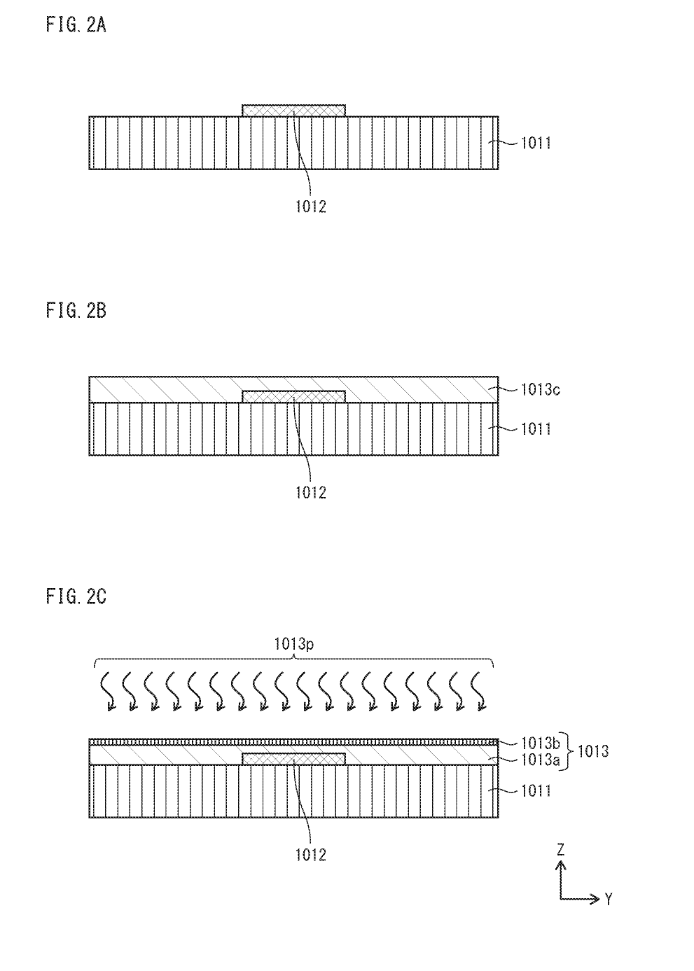

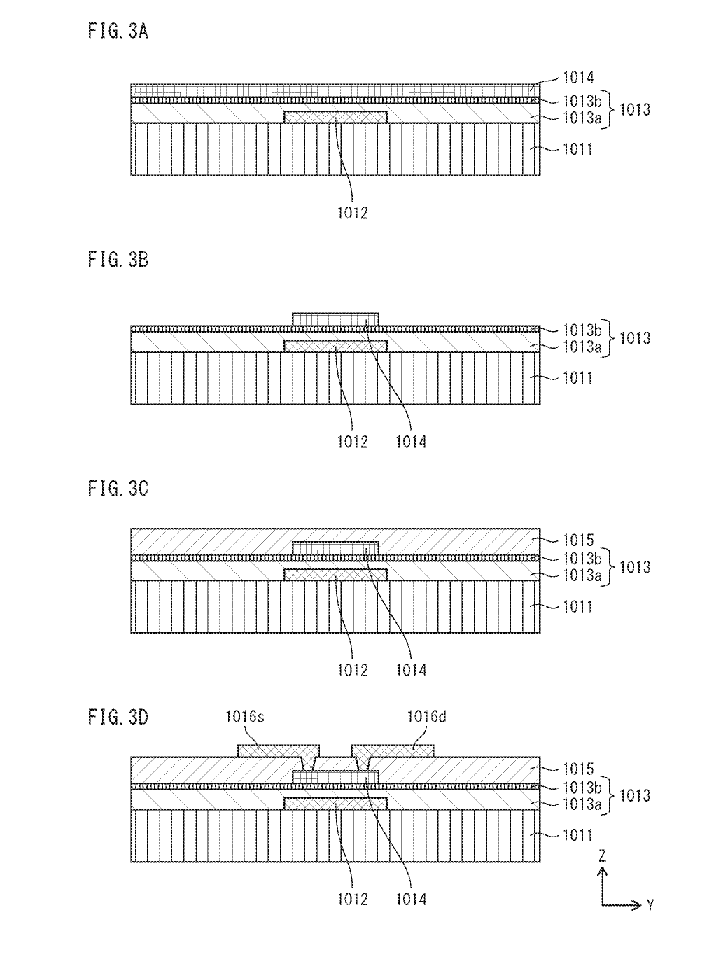

A manufacturing method of the TFT 101 is explained with reference to FIGS. 2A-2C and 3A-3D.

(1) Formation of Gate Electrode 1012

First, as shown in FIG. 2A, a gate electrode 1012 is formed on a substrate 1011. For example, a glass substrate is prepared as the substrate 1011, and then a metal film is formed on the substrate 1011 using a sputtering method. The metal film includes an Mo film and a Cu film that are layered in respective order. Further, the metal film is patterned using a photolithography method and a wet etching method. As a result, the gate electrode 1012 is formed. The gate electrode 1012 has for example an approximate thickness of 20 nm to 500 nm. Wet etching of the Mo film and the Cu film is performed for example with use of an etching solution containing hydrogen peroxide (H₂O₂) and organic acid.

(2) Formation of Gate Insulating Layer 1013

Next, as shown in FIG. 2B, an insulating layer 1013c is formed on the substrate 1011 so as to cover the gate electrode 1012. The insulating layer 1013c includes silicon and one of nitrogen and oxygen. For example, the insulating layer 1013c is formed by forming a silicon oxide film or a silicon nitride film using a plasma CVD method on the substrate 1011 on which the gate electrode 1012 is formed. The silicon oxide film is formed for example by introducing silane (SiH₄) gas and nitrous oxide (N₂O) gas. The silicon nitride film is formed for example by introducing silane (SiH₄) gas, ammonia (NH₃) gas, and nitrogen (N₂) gas. The insulating layer 1013c has for example a thickness of 50 nm to 300 nm. Note that the insulating layer 1013c is one aspect of the first film in the present embodiment.

Next, as shown in FIG. 2C, a second gate insulating layer 1013b is formed so as to include silicon, nitrogen, and oxygen by performing plasma processing to introduce the other of nitrogen and oxygen into the insulating layer 1013c from above on the Z-axis. As a result, a gate insulating layer 1013 is formed so as to include the first gate insulating layer 1013a as a lower surface thereof and the second gate insulating layer 1013b as an upper surface thereof.

Specifically, in the case where the insulating layer 1013c is for example a silicon oxide film, plasma nitridation processing 1013p is performed under atmosphere of ammonia gas or nitrogen gas to form a silicon oxynitride film as the upper surface of the insulating layer 1013c. As a result, the gate insulating layer 1013 is formed, which includes the first gate insulating layer 1013a formed from a silicon oxide film and the second gate insulating layer 1013b formed from a silicon oxynitride film.

Also, in the case where the insulating layer 1013c is for example a silicon nitride film, plasma oxidation processing 1013p is performed under atmosphere of oxygen (O₂) gas to form a silicon oxynitride film as the upper surface of the insulating layer 1013c. As a result, the gate insulating layer 1013 is formed, which includes the first gate insulating layer 1013a formed from a silicon nitride film and the second gate insulating layer 1013b formed from a silicon oxynitride film. Note that the second gate insulating layer 1013b is one aspect of the second film in the present embodiment.

(3) Formation of Channel Layer 1014

Next, as shown in FIG. 3A, a channel layer 1014 is formed on the gate insulating layer 1013 so as to face the gate electrode 1012. For example, sputtering is performed on a target material with a composition ratio of In:Ga:Zn=1:1:1 under an oxygen atmosphere. As a result, an amorphous IGZO film is formed as a channel layer 1014. The channel layer 1014 has for example an approximate thickness of 20 nm to 200 nm.

Next, as shown in FIG. 3B, the channel layer 1014 is patterned using the photolithography method and the wet etching method. Wet etching of an InGaZnO film is performed for example with use of an etching solution containing phosphoric acid (HPO₄), nitric acid (HNO₃), acetic acid (CH₃COOH), and water.

(4) Formation of Channel Protection Layer 1015

Next, as shown in FIG. 3C, a channel protection layer 1015 is formed on the gate insulating layer 1013 so as to cover the channel layer 1014. For example, the channel protection layer 1015 is formed by forming a silicon oxide film on the gate insulating layer 1013 and the channel layer 1014 using the plasma CVD method or the like. The channel protection layer 1015 has for example an approximate thickness of 50 nm to 500 nm.

(5) Formation of Source Electrode 1016s and Drain Electrode 1016d

Next, as shown in FIG. 3D, contact holes are formed in the channel protection layer 1015, and then a source electrode 1016s and a drain electrode 1016d are formed on the channel protection layer 1015 with an interval therebetween. The source electrode 1016s and the drain electrode 1016d are also each formed in a different one of the contact holes, which are formed in the channel protection layer 1015, that is, on the channel layer 1014.

Specifically, the channel protection layer 1015 is etched using the photolithography method and the dry etching method. As a result, the contact holes are formed on respective regions functioning as a source region and a drain region of the channel layer 1014. In the case where the channel protection layer 1015 is formed for example from a silicon oxide film, dry etching is performed using a reactive ion etching (RIE) method. In this case, carbon tetrafluoride (CF₄) gas or oxygen (O₂) gas is used as etching gas. Parameters such as gas flow rate, pressure, electrical power to be applied, and frequency are appropriately set in accordance with the substrate size, the set film thickness for etching, and so on.

The source electrode 1016s and the drain electrode 1016d are formed with an interval therebetween in the respective contact holes, which are formed in the channel layer 1014, and on the channel protection layer 1015. For example, a metal film, which includes Mo film, a Cu film, and a CuMn film that are layered in respective order, is formed using the sputtering method in the contact holes and on the channel protection layer 105. Further, the metal film is patterned using the photolithography method and the wet etching method. As a result, the source electrode 1016s and the drain electrode 1016d are formed. The source electrode 1016s and the drain electrode 1016d each have for example an approximate thickness of 100 nm to 500 nm. Wet etching of the Mo film, the Cu film, and the CuMn film is performed for example with use of an etching solution containing hydrogen peroxide (H₂O₂) and organic acid.

Through the above processes, it is possible to manufacture the TFT 101.

4. Achievable Effects

As shown in FIG. 1, the TFT 101 includes the gate electrode 1012, the source electrode 1016s, and the drain electrode 1016d. The gate electrode 1012 and each of the source electrode 1016s and the drain electrode 1016d are disposed with an interval therebetween. Also, the source electrode 1016s and the drain electrode 1016d are disposed with an interval therebetween. The TFT 101 also includes the channel layer 1014, which is disposed spaced from the gate electrode 1012 and is in contact with the source electrode 1016s and the drain electrode 1016d. The TFT 101 further includes the gate insulating layer 1013, which is disposed between the gate electrode 1012 and the channel layer 1014 and is in contact with the gate electrode 1012 and the channel layer 1014. In the TFT 101, the channel layer 1014 includes oxide semiconductor, and a region of the gate insulating layer 1013 that is in contact with the channel layer 1014 is the second gate insulating layer 1013b that includes silicon, nitrogen, and oxygen. Also, in the TFT 101, the second gate insulating layer 1013b is formed by performing plasma processing to introduce, into the insulating layer 1013c including silicon and one of nitrogen and oxygen, the other of nitrogen and oxygen.

The following explains effects exhibited by the above structure, specifically, effects exhibited by the second gate insulating layer 1013b included in the TFT 101.

(1) Structural Effects

i. Suppression of Occurrence of Defects

Generally, defects, which occur around an interface of the gate insulating layer 1013 with the channel layer 1014, trap carriers in the channel layer 1014, and this causes time-dependent threshold voltage shift of the TFT 101. In the TFT 101, compared with this, the second gate insulating layer 1013b is formed from an insulating film such as silicon oxynitride film. Such an insulating film has a dense structure and thereby is highly resistant to collision with high-energy ions, and has an interface in an excellent state with oxide semiconductor.

The gate insulating layer 1013 includes the second gate insulating layer 1013b having the above properties as a surface thereof, and accordingly is protected against damages such as collision with high-energy ions in the manufacturing process of the TFT 101. In other words, occurrence of defects is suppressed around the interface of the gate insulating layer 1013 with the channel layer 1014. As a result, the time-dependent threshold voltage shift is reduced in the TFT 101.

Note that, in the TFT 101, the second gate insulating layer 1013b should preferably include a layer having a nitrogen concentration of 2×10²⁰ cm⁻³ or higher. The nitrogen concentration of 2×10²⁰ cm⁻³ or higher allows to bond between silicon and hydrogen to sufficiently suppress damages on the second gate insulating layer 1013b (occurrence of defects) due to sputtering or the like. Accordingly, the time-dependent threshold voltage shift is reduced more certainly in this case.

Also, in the TFT 101, the second gate insulating layer 1013b should preferably have a thickness of 6 nm to 30 nm. The thickness of 6 nm or higher allows to use a region of a gate insulating layer in which a number of defects which trap carries generally exist (within 6 nm from an interface with a channel layer in a thickness direction) as the second gate insulating layer 1013b with less occurrence of defects. Accordingly, the time-dependent threshold voltage shift is reduced more effectively in this case.

Further, the thickness of 30 nm or lower allows to prevent excessive plasma processing. Therefore, it is possible to suppress occurrence of defects due to roughness of the interface of the second gate insulating layer 1013b with the channel layer 1014. Note that, in a general gate insulating layer, carriers trapped by the defects exist within 20 nm from the interface thereof with the channel layer 1014 in the thickness direction. Therefore, the second gate insulating layer 1013b only needs to have a thickness of 30 nm or less.

Also, the nitrogen concentration and the thickness of the second gate insulating layer 1013b are adjustable in accordance with conditions for plasma processing (gas to be used, processing period, gas flow rate, RF power, pressure, temperature, electrode interval, and so on). Further, the nitrogen concentration of the second gate insulating layer 1013b is quantifiable using secondary ion mass spectrometry (SIMS), and the thickness of the second gate insulating layer 1013b is quantifiable by cross-section analysis using a transmission electron microscope (TEM).

ii. Suppression of Amount of Contained Hydrogen

In the case where the channel layer 1014 is formed from oxide semiconductor, hydrogen, which exists around the interface of the gate insulating layer 1013 with the channel layer 1014, traps carriers in the channel layer 1014, and this causes time-dependent threshold voltage shift of the TFT 101. Also, when concentration of the hydrogen increases, hydrogen increasingly diffuses in the channel layer 1014. As a result, the channel layer 1014 is converted to be conductive.

Here, in the TFT 101, the second gate insulating layer 1013b is formed by performing plasma processing. For example, the second gate insulating layer 1013b is formed by performing plasma processing to nitride a surface of a silicon oxide film or by performing plasma processing to oxygenate a surface of a silicon nitride film.

This prevents mixing of unintended impurities, particularly hydrogen, into the second gate insulating layer 1013b. In other words, in the TFT 101, it is possible to suppress increase of an amount of hydrogen of the second gate insulating layer 1013b. Therefore, although the TFT 101 includes the channel layer which is formed from oxide semiconductor, time-dependent threshold voltage shift and conversion of the channel layer 1014 to be conductive are reduced, and as a result stable properties are achieved.

In the TFT 101, the second gate insulating layer 1013b should preferably have a hydrogen concentration of 2×10²⁰ cm⁻³ or less. The hydrogen concentration of 2×10²⁰ cm⁻³ or less sufficiently reduces trapping of carriers in the channel layer 1014 due to hydrogen contained in the second gate insulating layer 1013b. Accordingly, the time-dependent threshold voltage shift is reduced more certainly in this case.

The hydrogen concentration of the second gate insulating layer 1013b is adjustable by hydrogen concentration of the insulating layer 1013c, which is precursor of the second gate insulating layer 1013b. For example, the insulating layer 1013c should be formed from an insulating film with a smaller amount of contained hydrogen such as a silicon oxide film. Also, the hydrogen concentration of the second gate insulating layer 1013b is quantifiable using the SIMS.

(2) Effects on Manufacture

The ion implantation method is utilizable in order to form a silicon oxynitride film from a silicon oxide film or a silicon nitride film. However, the use of the ion implantation method causes occurrence of defects in the formed silicon oxynitride film due to collision with high-energy ions. Such defects need to be removed by performing anneal processing. In order to sufficiently suppress the threshold voltage shift of the TFT, it is necessary to form the substrate of the TFT from a highly heat-resistant material such as high-priced quartz glass.

Here, in the TFT 101, the second gate insulating layer 1013b is formed by performing plasma processing. According to the plasma processing, it is possible to reduce damages on the insulating layer 1013c which is precursor of the second gate insulating layer 1013b by adjusting conditions for the processing, thereby suppressing occurrence of new defects. Also, according to plasma surface processing, it is possible to fill defects caused by a forming method of the insulating layer 1013c (for example, a process at a low temperature such as the CVD method).

In other words, it is possible to sufficiently reduce defects in the second gate insulating layer 1013b at a time of formation, thereby avoiding the necessity of performing anneal process. In the TFT 101, therefore, even in the case where there are fewer limitations on material of the substrate, for example even in the case where the substrate is formed from a low heat-resistant glass, time-dependent threshold voltage shift is suppressed.

Further, compared with the ion implantation method, the plasma processing does not require any equipment such as a beam line, an accelerating electrode, an insulating transformer for insulating an ion source at a high voltage, and an insulating signal line associated with the insulating transformer. Further, according to the plasma processing, measures for shielding and protection should be taken within a chamber, and accordingly a shielded room is basically unnecessary. Therefore, in the TFT 101, it is possible to suppress increase of manufacturing costs in terms of necessary equipment for the processing and the number of processes relating to the processing. Further, it is possible to perform processing on large-sized substrates, which are difficult to deal with using the ion implantation method, and there are fewer limitations on the size of the substrate.

From the above, although the TFT 101 includes the channel layer which is formed from oxide semiconductor, time-dependent threshold voltage shift is reduced, there are fewer limitations on the utilizable material and size of the substrate, and therefore increase of manufacturing costs is suppressed.

5. Verification by Example

The following verifies effects of the TFT 101 and a comparative example thereof that were actually manufactured.

(1) Structure of Example and Comparative Example

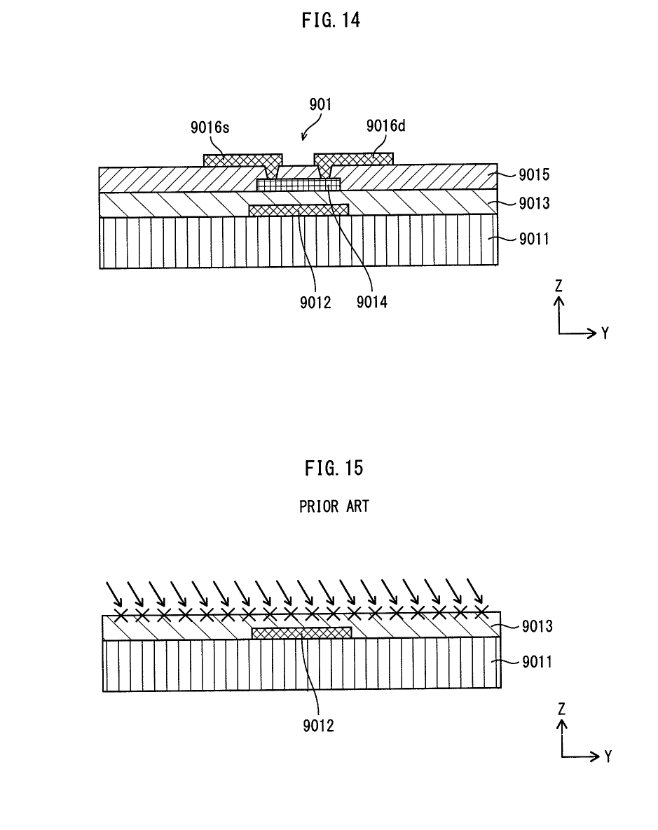

The following explains an example of the TFT 101 (hereinafter, referred to as an example) and an example of the TFT 901 having a structure shown in FIG. 14 (hereinafter, referred to as a comparative example), with reference to reference numerals in FIGS. 1 and 14, respectively.

The substrates 1011 and 9011 were formed from a non-alkali glass substrate. The gate electrodes 1012 and 9012 were formed from a molybdenum-tungsten film and set to have a thickness of 75 nm. The first gate insulating layer 1013a of the gate insulating layer 1013 was formed from a layered film including a silicon nitride film and a silicon oxide film. The second gate insulating layer 1013b of the gate insulating layer 1013 was formed from a silicon oxynitride film.

Here, the second gate insulating layer 1013b was formed as follows. First, as precursor, the insulating layer 1013c was formed, which includes a silicon nitride film and a silicon oxide film that are layered in respective order. The silicon nitride film was set to have a thickness of 65 nm and the silicon oxide film was set to have a thickness of 85 nm. Then, plasma nitridation processing was performed on the silicon oxide film, which is an upper surface of the insulating layer 1013c, to form the second gate insulating layer 1013b. The second gate insulating layer 1013b was set to have a thickness of 20 nm. The plasma processing was performed under the following two types of conditions.

i. First Conditions for Plasma Processing

gas to be used=NH₃

processing period=120 sec

gas flow rate=100 sccm

RF power=150 W

pressure=3 Torr

temperature=400 degrees C.

electrode interval=550 mils

ii. Second Conditions for Plasma Processing

gas to be used=N₂

processing period=120 sec

gas flow rate=2000 sccm

RF power=150 W

pressure=3 Torr

temperature=400 degrees C.

electrode interval=550 mils

The gate insulating layer 9013 was formed from a layered film including a silicon nitride film and a silicon oxide film, which was formed by the same method as the insulating layer 1013c in the example but did not undergone plasma nitridation processing.

The channel layers 1014 and 9014 were formed from an amorphous InGaZnO film, and were set to have a thickness of 60 nm. The channel protection layers 1015 and 9015 were formed from a silicon oxide film, and were set to have a thickness of 120 nm. The source electrodes 1016s and 9016s and the drain electrodes 1016d and 9016d were formed from an Mo film, and were set to have a thickness of 100 nm.

As clear from above, difference between the example and the comparative example lies only in whether plasma processing has been performed or not in a process of forming the gate insulating layer.

(2) Nitrogen Concentration and Hydrogen Concentration in Gate Insulating Layers of Example and Comparative Example

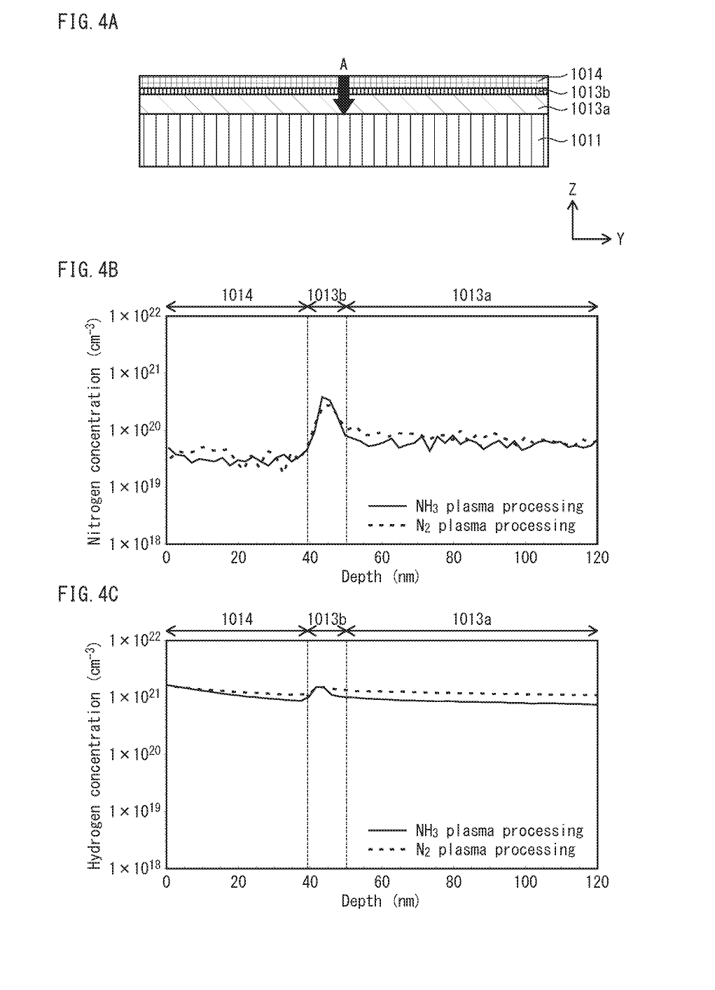

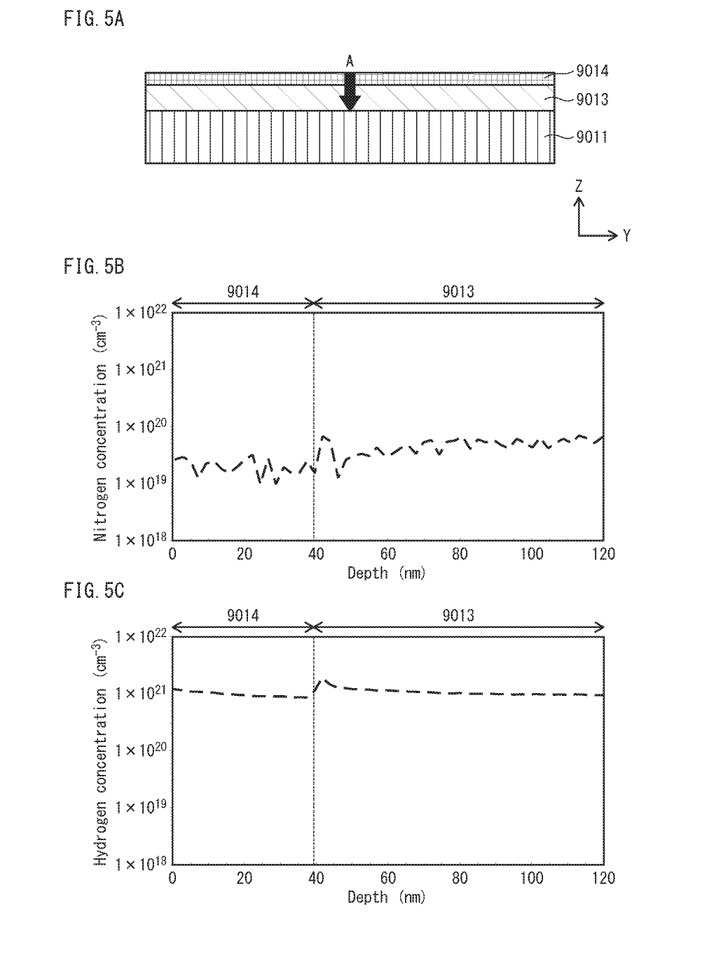

FIGS. 4A-4C and FIGS. 5A-5C show results of profiles measured using the SIMS with respect to the example and the comparative example, respectively. With respect to the example as shown in an arrow A in FIG. 4A, a profile was measured, which moves from the channel layer 1014 to the first gate insulating layer 1013a through the second gate insulating layer 1013b. Also, with respect to the comparative example as shown in an arrow A in FIG. 5A, a profile was measured, which moves from the channel layer 9014 to the gate insulating layer 9013.

FIGS. 4B and 5B show profiles of the nitrogen concentration in the example and the comparative example, respectively. As shown in FIGS. 4B and 5B, a region of the second gate insulating layer 1013b in the example has a higher nitrogen concentration than that of the gate insulating layer 9013 in the comparative example, and including a layer having a nitrogen concentration of 2×10²⁰ cm⁻³ or higher. In other words, the second gate insulating layer 1013b in the example includes a silicon oxynitride film with fewer defects because of sufficient nitrogen addition resulting from the plasma processing.

FIGS. 4C and 5C show profiles of the hydrogen concentration in the example and the comparative example, respectively. As shown in FIGS. 4C and 5C, the second gate insulating layer 1013b in the example has an equivalent nitrogen concentration to that of the gate insulating layer 9013 in the comparative example, and specifically has a hydrogen concentration of 2×10²⁰ cm⁻³ or less. In other words, the second gate insulating layer 1013b in the example includes a silicon oxynitride film by performing the plasma processing to suppress increase of an amount of contained hydrogen.

(3) Time-Dependent Threshold Voltage Shift in Example and Comparative Example

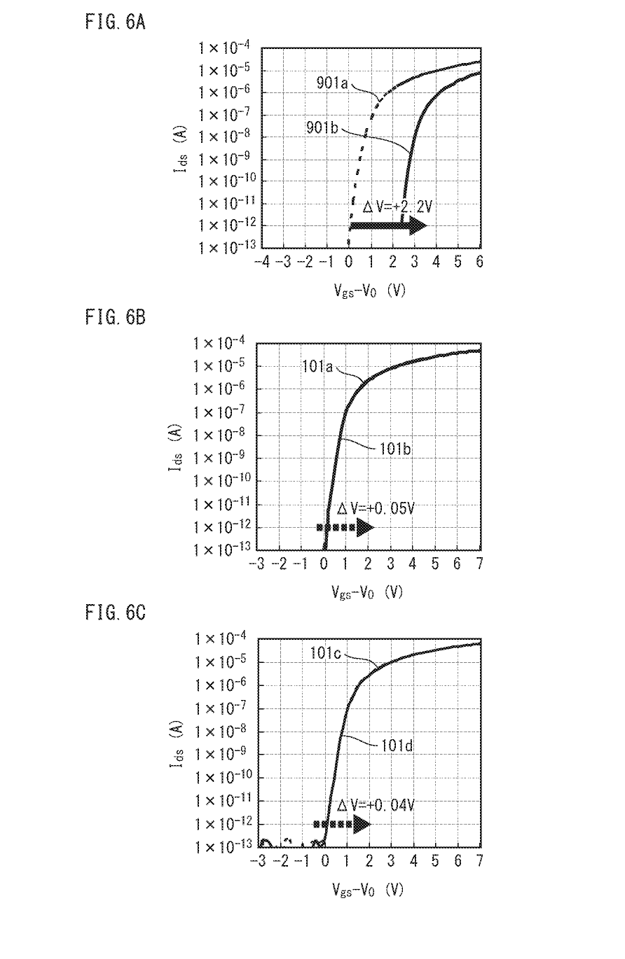

FIGS. 6A-6C show behavior of the threshold voltage shift between before and after stress application in the example and the comparative example. FIG. 6A shows behavior of the threshold voltage shift in the comparative example, FIG. 6B shows behavior of the threshold voltage shift in the example in which ammonia gas was used for the plasma processing, and FIG. 6C shows behavior of the threshold voltage shift in the example in which nitrogen gas was used for the plasma processing.

Also, graphs in FIGS. 6A-6C each have a vertical axis indicating drain current (I_{ds}) of the TFT and a horizontal axis indicating gate-source voltage (V_{gs}) of the TFT. Note that a relative value (V_{gs}−V₀) is used as the scale on the horizontal axis for the purpose of simplifying the comparison of the graphs, and reference V₀ of the relative value indicates the threshold voltage of the TFT before stress application in the graphs.

Further, in the graphs in FIGS. 6A-6C, dashed lines (901a, 101a, and 101c) each indicate the relationship between the drain current and the gate-source voltage before stress application, and solid lines (901b, 101b, and 101d) each indicate the relationship between the drain current and the gate-source voltage after stress application. Note that the following stress conditions were used: a gate-source voltage of +20 V; a drain-source voltage of 0 V; a temperature of 90 degrees C.; and an application period of 2000 seconds.

As shown in FIG. 6A, the threshold voltage shift after stress application in the comparative example was 2.2 V. Compared with this, as shown in FIGS. 6B and 6C, the threshold voltage shift after stress application in the comparative example was +0.05 V for the case where ammonia gas was used for the plasma processing, and was +0.04 V for the case where nitrogen gas was used for the plasma processing. That is, the threshold voltage shift was reduced in the example.

Therefore, with respect to the TFT 101, it was demonstrated that even in the case where the channel layer 1014 includes oxide semiconductor, the threshold voltage shift is reduced.

### Embodiment 2

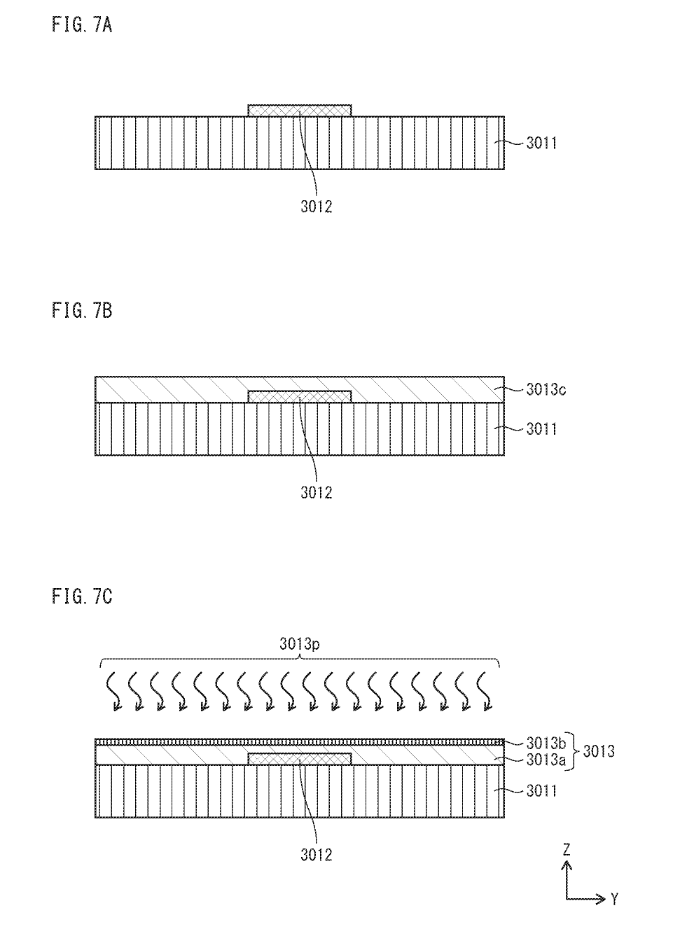

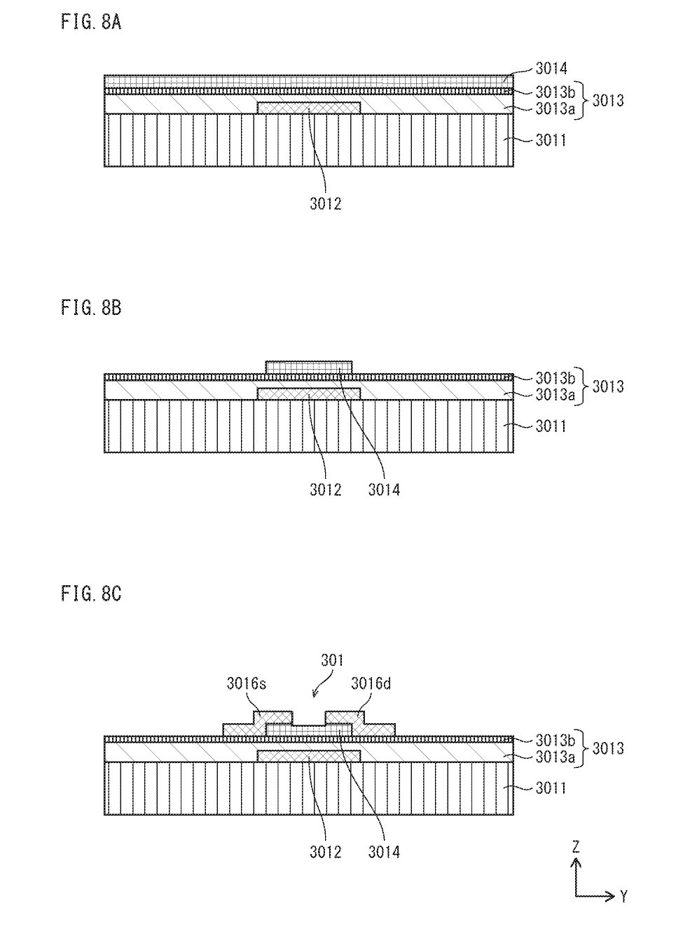

The following explains, as one aspect of the present disclosure, a TFT 301 relating to Embodiment 2 that is a bottom gate TFT with a channel etching structure, with reference to FIGS. 7A-7C and 8A-8C. FIGS. 7A-7C and 8A-8C correspond to FIGS. 2A-2C and 3A-3C, respectively.

1. Cross-Sectional Structure of TFT 301

FIG. 8C is a schematic cross-sectional view showing the TFT 301. As shown in FIG. 8C, a substrate 3011, a gate electrode 3012, a gate insulating layer 3013 including a first gate insulating layer 3013a and a second gate insulating layer 3013b, a channel layer 3014 have the same structures as those included in the TFT 101 relating to Embodiment 1 shown in FIG. 1.

As shown in FIG. 8C, on the other hand, the TFT 301 does not include the channel protection layer 1015, which is included in the TFT 101. Also, a source electrode 3016s and a drain electrode 3016d are directly formed with an interval therebetween on the gate insulating layer 3013 and the channel layer 3014.

2. Materials of TFT 301

The TFT 301 has the same compositional elements as those in the TFT 101 relating to Embodiment 1 except that the TFT 301 does not include a channel protection layer. Materials for the compositional elements can be the same as those in the TFT 101.

3. Manufacturing Method of TFT 301

A manufacturing method of the TFT 301 is explained with reference to FIGS. 7A-7C and 8A-8C. Note that specific methods of forming the compositional elements of the TFT 301 are the same as those in Embodiment 1 unless otherwise particularly described.

First, as shown in FIG. 7A, a gate electrode 3012 is formed on a substrate 3011. Next, as shown in FIG. 7B, an insulating layer 3013c is formed on the substrate 3011 so as to cover the gate electrode 3012. The insulating layer 3013c includes silicon and one of nitrogen and oxygen. Note that the insulating layer 3013c is one aspect of the first film in the present embodiment.

Next, as shown in FIG. 7C, a second gate insulating layer 3013b is formed so as to include silicon, nitrogen, and oxygen by performing plasma processing to introduce the other of nitrogen and oxygen into the insulating layer 3013c from above on the Z-axis. As a result, a gate insulating layer 3013 is formed so as to have the first gate insulating layer 3013a as a lower surface thereof and the second gate insulating layer 3013b as an upper surface thereof. Note that the second gate insulating layer 3013b is one aspect of the second film in the present embodiment.

Here, in Embodiment 2 as well as in Embodiment 1, the second gate insulating layer 3013b should preferably include a layer having a nitrogen concentration of 2×10²⁰ cm⁻³ or higher, and the second gate insulating layer 3013b should preferably have a hydrogen concentration of 2×10²⁰ cm⁻³ or less. Further, the second gate insulating layer 3013b should preferably have a thickness of 6 nm to 30 nm.

Next, as shown in FIG. 8A, a channel layer 3014 is formed on the gate insulating layer 3013 so as to face the gate electrode 3012. As shown in FIG. 8B, the channel layer 3014 is patterned.

Then, as shown in FIG. 8C, a source electrode 3016s and a drain electrode 3016d are formed with an interval therebetween on the gate insulating layer 3013 and the channel layer 3014. Specifically, the source electrode 3016s and the drain electrode 3016d are formed as follows. First, a metal film is formed using the sputtering method on the gate insulating layer 3013 so as to cover the channel layer 3014. The metal film includes an Mo film, a Cu film, and a CuMn film that are layered in respective order. Then, the metal film is patterned using the photolithography method and the wet etching method. As a result, the source electrode 3016s and the drain electrode 3016d are formed.

The source electrode 3016s and the drain electrode 3016d each have for example an approximate thickness of 100 nm to 500 nm. Wet etching of the Mo film, the Cu film, and the CuMn film is performed in the same manner as in Embodiment 1.

Through the above processes, it is possible to manufacture the TFT 301 relating to Embodiment 2.

4. Achievable Effects

The TFT 301 has the same structure of the gate insulating layer as the TFT 101. That is, the TFT 301 includes, in the region of the gate insulating layer 3013 that is in contact with the channel layer 3014, the second gate insulating layer 3013b which is formed by performing plasma processing and thereby has fewer defects and a less amount of contained hydrogen. Therefore, although the TFT 301 includes the channel layer of oxide semiconductor, the threshold voltage shift is reduced, there are fewer limitations on the utilizable material and size of the substrate, and therefore increase of manufacturing costs is suppressed.

### Embodiment 3

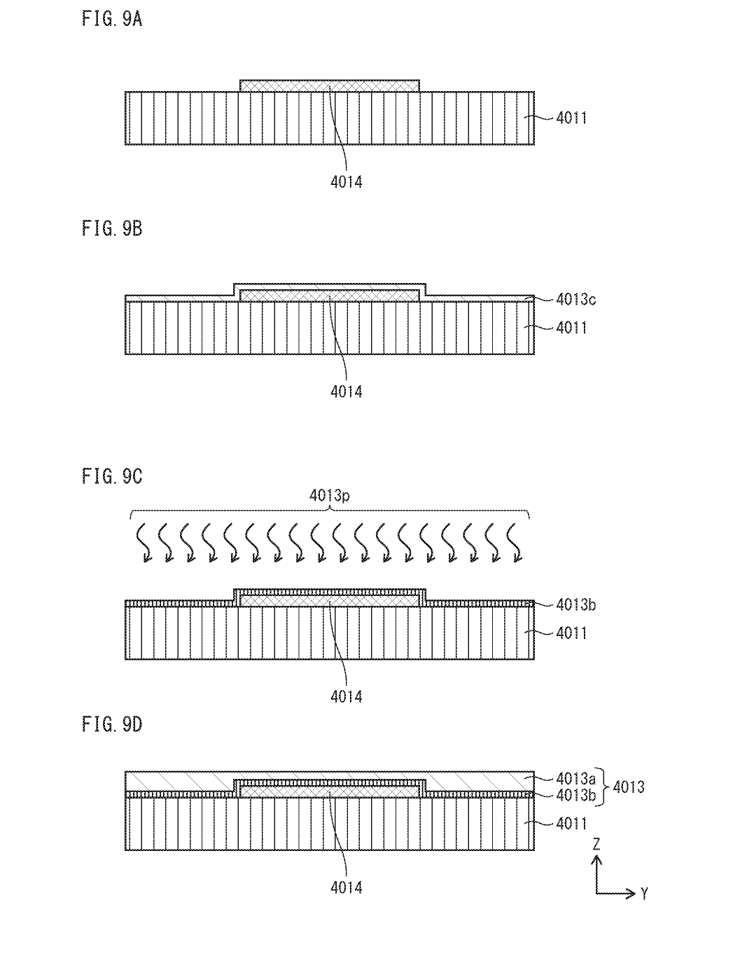

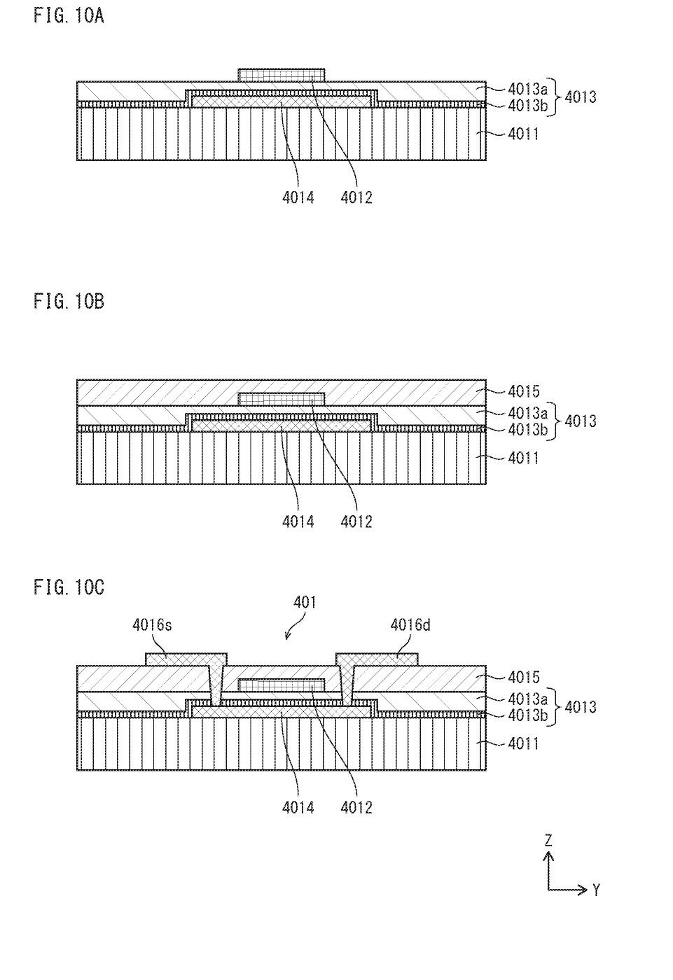

The following explains, as one aspect of the present disclosure, a TFT 401 relating to Embodiment 3 that is a top gate TFT, with reference to FIGS. 9A-9D and 10A-10C. FIGS. 9A-9D and 10A-10C correspond to FIGS. 2A-2C and 3A-3C, respectively.

1. Cross-Sectional Structure of TFT 401

FIG. 10C is a schematic cross-sectional view showing the TFT 401. As shown in FIG. 10C, in the TFT 401, a channel layer 4014 is formed on a substrate 4011, and a gate insulating layer 4013 is formed on the substrate 4011 so as to cover the channel layer 4014. The gate insulating layer 4013 includes a second gate insulating layer 4013b in a region thereof that is in contact with the substrate 4011 and the channel layer 4014, and includes a first gate insulating layer 4013a on an upper surface of the second gate insulating layer 4013b.

Also, a gate electrode 4012 is formed on the gate insulating layer 4013, and an interlayer insulating layer 4015 is formed on the gate insulating layer 4013 so as to cover the gate electrode 4012.

Further, a source electrode 4016s and a drain electrode 4016d are formed on the interlayer insulating layer 4015. The source electrode 4016s and the drain electrode 4016d are each also formed in a contact hole that is formed in the gate insulating layer 4013 and the interlayer insulating layer 4015, and are connected with the channel layer 1014.

2. Materials of TFT 401

The TFT 401 has the same compositional elements as those in the TFT 101 relating to Embodiment 1 except that the TFT 401 includes the interlayer insulating layer 4015. The compositional elements of the TFT 401 are formed from the same materials of the TFT 101. Also, the interlayer insulating layer 4015 is formed from the same material of the channel protection layer 1015 included in the TFT 101.

3. Manufacturing Method of TFT 401

A manufacturing method of the TFT 401 is explained with reference to FIGS. 9A-9D and 10A-10C. Note that specific methods of forming the compositional elements of the TFT 401 are the same as those in Embodiment 1 unless otherwise particularly described.

First, as shown in FIG. 9A, a channel layer 4014 is formed on a substrate 4011. Next, as shown in FIG. 9B, an insulating layer 4013c is formed on the substrate 4011 so as to cover the channel layer 4014. The insulating layer 4013c includes silicon and one of nitrogen and oxygen. Note that the insulating layer 4013c is one aspect of the first film in the present embodiment.

Next, as shown in FIG. 9C, a second gate insulating layer 4013b is formed so as to include silicon, nitrogen, and oxygen by performing plasma processing to introduce the other of nitrogen and oxygen into the insulating layer 4013c. Then, as shown in FIG. 9D, a first gate insulating layer 4013a is formed on the second gate insulating layer 4013b. As a result, a gate insulating layer 4013 is formed so as to have the first gate insulating layer 4013a as an upper surface thereof and the second gate insulating layer 4013b as a lower surface thereof. Note that the second gate insulating layer 4013b is one aspect of the second film in the present embodiment.

Here, in Embodiment 3 as well as in Embodiment 1, the second gate insulating layer 4013b should preferably include a region having a nitrogen concentration of 2×10²⁰ cm⁻³ or higher, and the second gate insulating layer 4013b should preferably have a hydrogen concentration of 2×10²⁰ cm⁻³ or less. Further, the second gate insulating layer 4013b should preferably have a thickness of 6 nm to 30 nm.

Next, as shown in FIG. 10A, a gate electrode 4012 is formed on the gate insulating layer 4013 so as to face the channel layer 4014. As shown in FIG. 10B, an interlayer insulating layer 4015 is formed on the gate insulating layer 4013 so as to cover the gate electrode 4012. For example, the channel protection layer 4015 is formed by forming a silicon oxide film using the plasma CVD method or the like on the gate insulating layer 4013 on which the gate electrode 4012 is formed. The interlayer insulating layer 4015 has for example an approximate thickness of 50 nm to 500 nm.

Next, as shown in FIG. 10C, contact holes are formed in the gate insulating layer 4013 and the interlayer insulating layer 4015, and a source electrode 4016s and a drain electrode 4016d are formed on the interlayer insulating layer 4015 with an interval therebetween. The source electrode 4016s and the drain electrode 4016d are also each formed in a different one of the contact holes, that is, on the channel layer 4014. Also, the source electrode 4016s and the drain electrode 4016d are each formed spaced from the gate electrode 4012.

Through the above processes, it is possible to manufacture the TFT 401 relating to Embodiment 3.

4. Achievable Effects

As well as the TFT 101, the TFT 401 includes, in the region of the gate insulating layer 4013 that is in contact with the channel layer 4014, the second gate insulating layer 4013b which is formed by performing plasma processing having and thereby has fewer defects and a less amount of contained hydrogen. Therefore, although the TFT 401 includes the channel layer of oxide semiconductor, the threshold voltage shift is reduced, there are fewer limitations on the utilizable material and size of the substrate, and therefore increase of manufacturing costs is suppressed.

### Embodiment 4

The following explains, as one aspect of the present disclosure, an organic EL display device 1 relating to Embodiment 4. The present embodiment is an example in which the TFT 101 relating to the above Embodiment 1 is applied to the organic EL display device 1.

1. Whole Structure of Organic EL Display Device 1

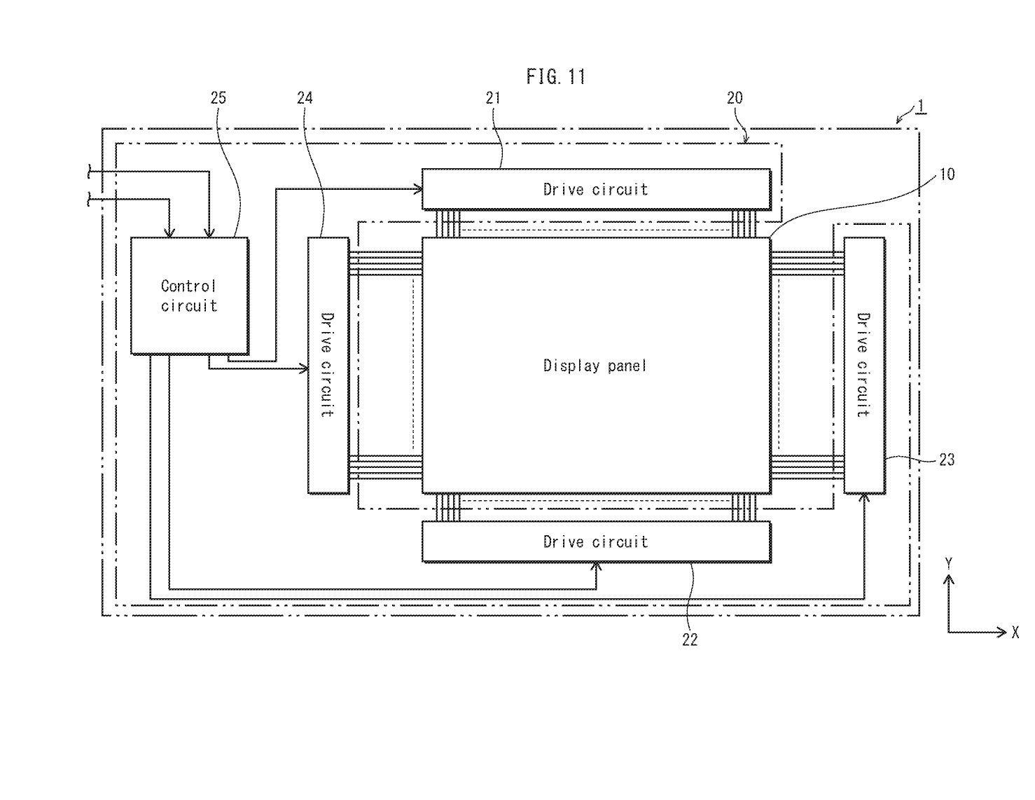

A structure of the organic EL display device 1 relating to the present embodiment is explained with reference to FIG. 11. As shown in FIG. 11, the organic EL display device 1 includes an organic EL display panel 10 and a drive control unit 20 that is connected with the organic EL display panel 10.

The organic EL display panel 10 is a panel that relies on electroluminescence phenomenon of organic materials. The organic EL display panel 10 includes a plurality of subpixels 10a that are arranged in a matrix. The subpixels 10a each correspond to a luminescent color such as red, green, and blue colors. The drive control unit 20 includes four drive circuits 21-24 and a control circuit 25. In the organic EL display device 1, the drive control unit 20 is not limited to this arrangement relative to the organic EL display panel 10.

2. Structure of Organic EL Display Panel 10

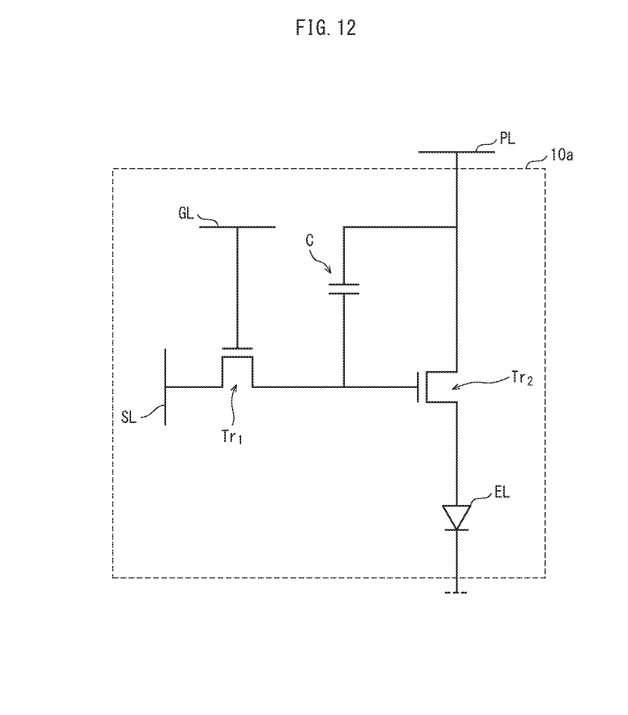

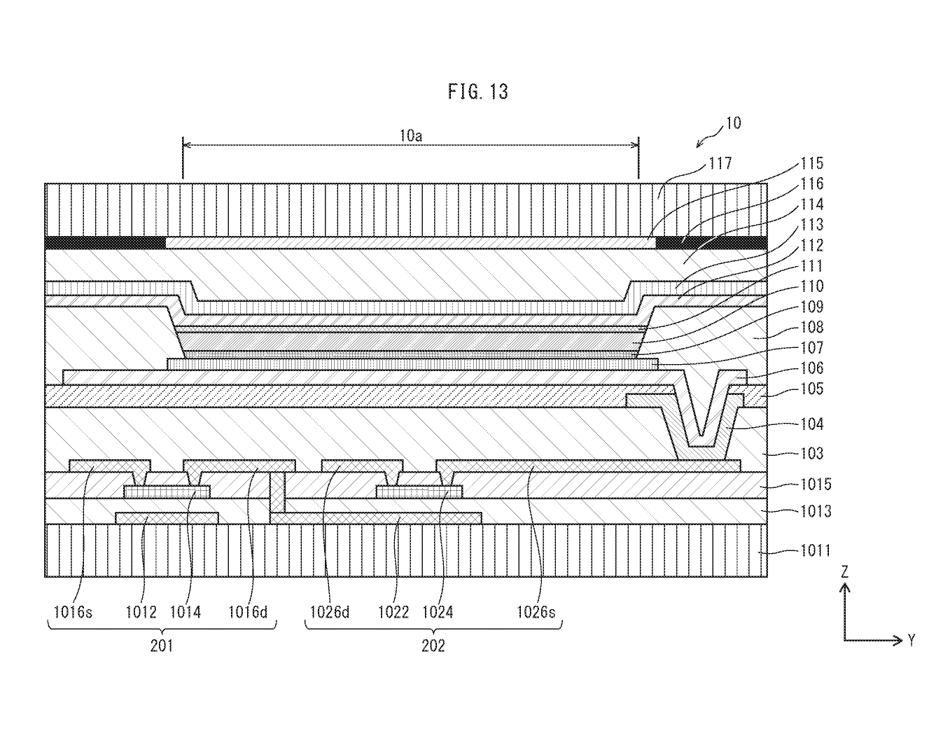

A structure of the organic EL display panel 10 is explained with reference to a circuit structure shown in FIG. 12 and a schematic cross-section shown in FIG. 13. Note that the structure in FIGS. 12 and 13 is shown in units of the subpixels 10a.

(1) Circuit Structure of Organic EL Display Panel 10

As shown in FIG. 12, the subpixel 10a, which constitutes the organic EL display panel 10, includes an organic EL element EL, a switching transistor Tr₁, a driving transistor Tr₂, and a capacitor C. The switching transistor Tr₁ is connected with the driving transistor Tr₂, the capacitor C, a signal line SL for connection with any one of the drive circuits 21-24, and a gate line GL. The driving transistor Tr₂ is connected with the capacitor C, the switching transistor Tr₁, the organic EL element EL, and a power line PL that externally supplies high current.

According to this structure, when the switching transistor Tr₁ is turned on in accordance with a signal from the gate line GL, a signal voltage that is supplied through the signal line SL is accumulated in the capacitor C and is held for a certain period. The held signal voltage determines conductance of the driving transistor Tr₂. Also, the conductance of the driving transistor Tr₂ determines drive current that is supplied from power line PL to the organic EL element EL. Therefore, the organic EL element EL emits light of a tone corresponding to the signal voltage for a certain period.

The organic EL display panel 10 displays, as an image, aggregation of luminescent colors of the subpixels 10a on which tone control is performed. That is, the organic EL element EL is one aspect of the pixel part in the present embodiment.

(2) Cross-Sectional Structure of Organic EL Display Panel 10

As shown in FIG. 13, the organic EL display panel 10 includes a TFT 201 that is formed on a substrate 1011. The TFT 201 includes a gate electrode 1012, a channel layer 1014, a source electrode 1016s, and a drain electrode 1016d. Further, a TFT 202 is formed spaced from the TFT 201. The TFT 202 includes a gate electrode 1022, a channel layer 1024, a source electrode 1026s, and a drain electrode 1026d.

Here, the TFT 201 corresponds to the switching transistor Tr₁ shown in FIG. 12, and the TFT 202 corresponds to the driving transistor Tr₂ shown in FIG. 12.

Also, a gate insulating layer 1013 is formed so as to cover the gate electrodes 1012 and 1022. Further, a channel protection layer 1015 is formed so as to cover the channel layers 1014 and 1024.

Here, although not shown in the figure, the gate insulating layer 1013 includes a first gate insulating layer 1013a and a second gate insulating layer 1013b. Therefore, the TFTs 201 and 202 have the same structure as the TFT 101 relating to Embodiment 1.

Also, as well as in the circuit structure shown in FIG. 12, the drain electrode 1016d, which is included in the TFT 201, is also formed in a contact hole that is formed in part of the gate insulating layer 1013 and the channel protection layer 1015 which are positioned on the gate electrode 1022 included in the TFT 202. Accordingly, the drain electrode 1016d is connected with the gate electrode 1022.

Further, a passivation layer 103 is formed on the channel protection layer 1015 so as to cover the source electrodes 1016s and 1026s and the drain electrodes 1016d and 1026d.

Further, an extraction electrode 104 is formed on the passivation layer 103. The extraction electrode 104 is also formed along a lateral surface of a contact hole that is formed in the passivation layer 103 which is formed on the source electrode 1026s. Accordingly, the extraction electrode 104 is connected with the source electrode 1026s. Further, a planarization layer 105 is formed so as to cover the extraction electrode 104.

Further, an anode 106 is formed on the planarization layer 105. The anode 106 is also formed along a lateral surface of a contact hole that is formed in part of the planarization layer 105, which is positioned on the extraction electrode 104. Accordingly, the anode 106 is connected with the extraction electrode 104. Further, a hole injection layer 107 is formed on a main surface of the anode 106.

Further, a bank 108 is formed on the planarization layer 105, the anode 106, and the hole injection layer 107 so as to surround a region corresponding to a light-emitting part (the subpixel 10a). Further, a hole transportation layer 109, an organic light-emitting layer 110, and an electron transportation layer 111 are formed in respective order on an opening that results from being surrounded by the bank 108, which is positioned on the hole injection layer 107. Further, a cathode 112 and a sealing layer 113 are formed in respective order on the bank 108 and the electron transportation layer 111.

Further, a color filter 115 is disposed, above the sealing layer 113, in a region including a region corresponding to the subpixel 10a. A light shielding layer 116 is disposed around the color filter 115. Further, a sealing resin layer 114 is filled between the sealing layer 113 and each of the color filter and the light shielding layer 116. Finally, a substrate 117 is disposed on the color filter 115 and the light shielding layer 116.

Note that the organic EL display panel 10 is a display panel of a so-called top emission type that has an image display surface on the upper side on the Z-axis in FIG. 13.

3. Materials of Organic EL Display Panel 10

Compositional elements of the organic EL display panel 10 are formed for example from materials as shown below. Note that compositional elements of the TFTs 201 and 202 are formed from the same materials of the TFT 101 relating to Embodiment 1, and accordingly explanation thereof is omitted.

(1) Passivation Layer 103

The passivation layer 103 is formed from material that has high adhesion with the source electrodes 1016s and 1026s and the drain electrodes 1016d and 1026d, and has barrier properties against moisture and oxygen. The passivation layer 103 for example has a single-layer structure or a multi-layer structure including a silicon oxide film, a silicon nitride film, a silicon oxynitride film, and an aluminum oxide film.

(2) Extraction Electrode 104

The extraction electrode 104 is formed for example from the same materials of the gate electrodes 1012 and 1022.

(3) Planarization Layer 105

The planarization layer 105 are formed for example from an organic compound such as polyimide, polyamide, and acrylic resin material.

(4) Anode 106

The anode 106 is formed for example from metal material containing silver or aluminum. Note that a display panel of a top emission type such as the organic EL display panel 10 should preferably have a surface part that is highly light-reflective.

(5) Hole Injection Layer 107

The hole injection layer 107 is formed for example from oxide such as silver, molybdenum, chromium, vanadium, tungsten, nickel, and iridium, or conductive polymer material such as polyethylenedioxythiophene (PEDOT).

(6) Bank 108

The bank 108 is formed for example from organic insulating material such as resin. Specific examples of such organic insulating material include acrylic resin, polyimide resin, and novolac phenolic resin. The bank 108 should desirably be formed from material that has organic solvent resistance and is highly resistant to organic solution so as not to excessively deform, transform, and so on due to etching processing and baking processing, and so on. Also, fluorine processing may be performed on a surface of the bank 108 so as to provide the surface with water repellency. Further, the bank 108 may have the multi-layer structure including layers formed from these materials.

(7) Hole Transportation Layer 109

The hole transportation layer 109 is formed from high molecular compound that does not have hydrophilic group. For example, the hole transportation layer 109 is formed from polyfluorene, polyfluorene derivative, polyallylamine, or polyallylamine derivative.

(8) Organic Light-Emitting Layer 110

The organic light-emitting layer 110 is formed from luminous organic material using a wet printing method. Specifically, the organic light-emitting layer 110 is formed for example from fluorescent material such as compound, derivative, and complex that are disclosed in Japanese Patent Application Publication No. H05-163488.

(9) Electron Transportation Layer 111

The electron transportation layer 111 is formed for example from oxydiazole derivative (OXD), triazole derivative (TAZ), phenanthroline derivative (BCP), or the like.

(10) Cathode 112

In a display panel of a top emission type such as the organic EL display panel 10, the cathode 112 needs to be formed from light-transmissive material such as ITO and indium zinc oxide (IZO). Alternatively, the cathode 112 may be formed from a film containing alkali metal, alkaline-earth metal, or halide thereof, or have the multi-layer structure including the film and a film containing silver that are layered in respective order. Further, a high-transparent layer for adjusting refractive index may be provided on the film containing silver in order to improve light-extraction efficiency.

(11) Sealing Layer 113

The sealing layer 113 is formed from material that has barrier properties against moisture and oxygen. In the organic EL display panel 10, which is of a top emission type, the sealing layer 113 needs to be formed from light-transmissive material such as a silicon nitride film and a silicon oxynitride film.

(12) Sealing Resin Layer 114

The sealing resin layer 114 is formed from material that has adhesion properties for adhering the sealing layer 113 and each of the color filter 115 and the light shielding layer 116 together. For example, the sealing resin layer 114 is formed from resin material such as epoxy resin, acrylic resin, and silicone resin.

4. Manufacturing Method of Organic EL Display Panel 10

The outline of a manufacturing method of the organic EL display panel 10 is explained with reference to FIG. 13.

As shown in FIG. 13, the substrate 1011 is prepared, and the TFTs 201 and 202 are formed on the substrate 1011. The TFTs 201 and 202 are formed in the same manner as in Embodiment 1.

Here, as shown in FIG. 13, the organic EL display panel 10 has the structure in which the drain electrode 1016d, which is included in the TFT 201, is connected with the gate electrode 1022, which is included in the TFT 202.

This structure is for example achieved as follows. First, in the process of forming the contact hole in the channel protection layer 1015, as shown in FIG. 13, the gate insulating layer 1013 and the channel protection layer 1015, which are respectively positioned on and above the gate electrode 1022, are partially etched to form a contact hole. Then, in the process of forming the drain electrode 1016d, the drain electrode 1016d is also formed in the contact hole, and is connected with the gate electrode 1022.

Next, as shown in FIG. 13, the passivation layer 103 is formed on the channel protection layer 1015 so as to cover the source electrodes 1016s and 1026s and the drain electrodes 1016d and 1026d. Also, a contact hole is formed in the passivation layer 103 so as to be positioned on part of the source electrode 1026s. The passivation layer 103 is formed for example by forming an insulating film using the plasma CVD method, the sputtering method, or the like, and forming a contact hole using the photolithography method and the etching method.

Then, as shown in FIG. 13, the extraction electrode 104 is formed on the passivation layer 103. The extraction electrode 104 is formed along a lateral surface of the contact hole, which is formed in the passivation layer 103, and is connected with the source electrode 1026s. The extraction electrode 104 is formed for example by patterning a metal film, which is formed using the sputtering method.

Next, as shown in FIG. 13, the planarization layer 105, which is formed from an insulating material, is formed on the passivation layer 103 and the extraction electrode 104. Also, a contact hole is formed in the planarization layer 105 so as to be positioned on part of the extraction electrode 104. Further, an upper surface of part of the planarization layer 105 in the Z-axis direction other than the contact hole is substantially planarized.

Next, as shown in FIG. 13, the anode 106 is formed on the planarization layer 105. The anode 106 is sectioned in units of the subpixels 10a. The anode 106 is formed along a lateral surface of the contact hole, which is formed in the planarization layer 105, and is connected with the extraction electrode 104. The anode 106 is formed for example by forming a metal film using the sputtering method, a vacuum deposition method, or the like, and etching the metal film in units of the subpixels 10a.

Then, the hole injection layer 107 is formed on the anode 106. As shown in FIG. 13, the hole injection layer 107 is formed in units of the subpixels 10a. The hole injection layer 107 is formed for example from argon gas and oxygen gas using the sputtering method.

Next, the bank 108 is formed on the planarization layer 105, the anode 106, and the hole injection layer 107. The bank 108 is formed for example by forming, on the planarization layer 105, the anode 106, and the hole injection layer 107, a layer that is formed from material containing photosensitive resin component and fluorine component using a spin-coat method or the like, and patterning an opening that corresponds to each subpixel 10a as shown in FIG. 13.

Next, as shown in FIG. 13, the hole transportation layer 109, the organic light-emitting layer 110, and the electron transportation layer 111 are layered on the hole injection layer 107 in respective order. The hole transportation layer 109 is formed for example by forming a film containing an organic compound using a printing method and burning the film. The organic light-emitting layer 110 and the electron transportation layer 111 are formed in the same manner.

Next, the cathode 112 and the sealing layer 113 are layered on the electron transportation layer 111 in respective order. As shown in FIG. 13, the cathode 112 and the sealing layer 113 are formed on the entire electron transportation layer 111 so as to cover a part that is exposed from the bank 108.

Next, the sealing resin layer 114 is formed on the sealing layer 113 by applying an adhesive resin material to the sealing layer 113, and a color filter panel which has been prepared in advance is bonded to the sealing resin layer 114. The color filter panel includes the color filter 115, the light shielding layer 116, and the substrate 117. As shown in FIG. 13, the color filter panel has a structure in which the color filter 115 is disposed in a position corresponding to the subpixel 10a on a lower surface of the substrate 117 in the Z-axis direction, and the light shielding layer 116 is disposed around the color filter 115.

The organic EL display panel 10 is complete through the above processes. Then, the organic EL display device 1 is formed by attaching the drive control unit 20 to the organic EL display panel 10 (see FIG. 11), and aging processing is performed on the organic EL display device 1. This completes the organic EL display device 1. The aging processing is for example by supplying power until hole mobility reaches 1/10 or less with respect to hole injection properties before the processing. Specifically, power supply processing is performed for a predetermined period such that luminance is three times or higher than luminance at actual use time.

5. Achievable Effects

As well as the TFT 101 relating to Embodiment 1, the TFTs 201 and 202, which are included in the organic EL display device 1, each include, in the region of the gate insulating layer 1013 that is in contact with a corresponding one of the channel layers 1014 and 1024, a second gate insulating layer (not shown in the figure) which is formed using the plasma processing and thereby has fewer defects and a less amount of contained hydrogen. Therefore, although the TFTs 201 and 202 each include the channel layer of oxide semiconductor, the threshold voltage shift is reduced, and there are fewer limitations on the utilizable material and size of the substrate, and therefore increase of manufacturing costs is suppressed.

According to the organic EL display device 1 including the TFTs 201 and 202 as described above, therefore, deterioration of display quality is reduced and increase of manufacturing costs is suppressed while high-efficient electric characteristics of oxide semiconductor are achieved.

<Others>

The present disclosure is not limited to the above embodiments except the essential characteristic compositional elements thereof. For example, the present disclosure also includes an embodiment obtained through various types of modifications which could be conceived of by one skilled in the art to the above embodiments, an embodiment obtained through any combination of the compositional elements and the functions in the above embodiments without departing from the spirit of the present disclosure, and so on.

In Embodiment 1, the second gate insulating layer 1013b included in the TFT 101 is exemplified by a silicon oxynitride film. However, the second gate insulating layer 1013b is not limited to a pure silicon oxynitride film, and alternatively may be a silicon compound film that is composed of a silicon oxynitride film and substance other than hydrogen, nitrogen, oxygen, and silicon, or a film that is a mixture of the a silicon compound film and other substance.

Also, in Embodiment 1, the method of forming the second gate insulating layer 1013b is exemplified by plasma nitridation processing of a silicon oxide film or plasma oxidation processing of a silicon nitride film. Alternatively, plasma nitridation processing may be performed on a silicon compound film that contains oxygen, silicon, and substance other than hydrogen, nitrogen, oxygen, and silicon, or a film that is a mixture of the silicon compound film and other substance. Further alternatively; plasma oxidation processing may be performed on a silicon compound film that contains nitrogen, silicon, and substance other than hydrogen, nitrogen, oxygen, and silicon, or a film that is a mixture of the silicon compound film and other substance.

In Embodiments 1-4, a bottom gate type TFT is exemplified by an inverted-staggered TFT, and a top gate TFT is exemplified by a coplanar TFT. Alternatively, the bottom gate TFT may be a staggered one, and the top gate TFT may be an inverted-coplanar one.

In Embodiment 4, the structure of the TFT 101 relating to Embodiment 1 is used for both the switching transistor and the driving transistor. Alternatively, only one of the switching transistor and the driving transistor may have the same structure as the TFT 101. Further alternatively, the structure of the TFTs 301 or 401 may be used, instead of the TFT 101.

In Embodiment 4, as shown in FIG. 12, two transistors are included per subpixel. However, the number of transistors to be included per subpixel may be appropriately modified as necessary. For example, one transistor may be included per subpixel, or three or more transistors may be included per subpixel.

In Embodiment 4, the subpixels are arranged in a matrix. However, the arrangement of the subpixels is not limited to this. Alternatively, subpixels each emitting one of three colors of red, green, or blue each may be arranged at one of vertices of a triangle, for example. Further, the luminescent color of the subpixels is not limited to three colors of red, green, and blue, and may include other color. For example, the luminescent color may include one color of white, or include four colors of red, green, blue, and yellow.

The materials described in Embodiments 1-4 are just examples, and may appropriately be modified. For example, a substrate may be formed from flexible material in order to achieve a flexible display device. Further, the channel layer is not limited to be formed from oxide semiconductor in an amorphous state, and alternatively may be formed for example from multicrystalline InGaO.

In Embodiment 4, the organic EL display panel 10 is of the top emission type. Alternatively, a bottom emission type may be adoptable. In this case, the structure of the organic EL display panel 10 may be appropriately modified.

In Embodiment 4, the display device is exemplified by an organic EL display device. The display device not limited to organic EL display device, and is applicable to a liquid crystal display device employing a liquid crystal display panel, a field emission display device employing a field emission display panel, and the like. In these cases, like the organic EL element EL, a liquid crystal part and an electron emission part are equivalent to the pixel part, which is connected with the TFT. Further, the display device is applicable to an electronic paper, and the like.

Note that, in the present application, the term “on” does not indicate the upper direction (vertically upward direction) in an absolute spatial recognition, and is defined by a relative positional relation based on a layering order in a layer structure. Also, the term “above” is applied not only to the case where an interval is provided between two substances but also to the case where the two substances are adhered to each other.

### INDUSTRIAL APPLICABILITY

The TFT relating to the present disclosure is broadly utilizable to display devices such as television sets, personal computers, and mobile phones, or various types of electrical devices including TFTs.

### REFERENCE SIGNS LIST

1 organic EL display device

101, 201, 202, 301, 401, and 901 TFT

1011, 3011, 4011, and 9011 substrate

1012, 1022, 3012, 4012, and 9012 gate electrode

1013, 3013, 4013, and 9013 gate insulating layer

1014, 1024, 3014, 4014, and 9014 channel layer

1015 and 9015 channel protection layer

4015 interlayer insulating layer

1016s, 1026s, 3016s, 4016s, and 9016s source electrode

1016d, 1026d, 3016d, 4016d, and 9016d drain electrode

EL organic EL element (pixel part)

1. A thin-film transistor comprising:
a gate electrode;
a source electrode;
a drain electrode;
a channel layer that is in contact with the source electrode and the drain electrode, and includes oxide semiconductor; and
a gate insulating layer that is disposed between the gate electrode and the channel layer, and is in contact with the gate electrode and the channel layer, wherein
a region of the gate insulating layer that is in contact with the channel layer is a silicon compound film, and
the silicon compound film contains silicon, nitrogen, and oxygen, and is formed by performing plasma processing for introducing, into a film containing silicon and one of nitrogen and oxygen, the other of nitrogen and oxygen.

2. The thin-film transistor of claim 1, wherein
the channel layer is disposed between the gate electrode and each of the source electrode and the drain electrode.

3. The thin-film transistor of claim 1, wherein
the silicon compound film is a silicon oxynitride film resulting from performing plasma nitridation processing on a silicon oxide film or performing plasma oxidation processing on a silicon nitride film.

4. The thin-film transistor of claim 1, wherein
the silicon compound film includes a layer having a nitrogen concentration of 2×10²⁰ cm⁻³ or higher, and
the silicon compound film has a hydrogen concentration of 2×10²¹ cm⁻³ or less.

5. The thin-film transistor of claim 1, wherein
the silicon compound film has a thickness of 6 nm to 30 nm.

6. A display device comprising:
the thin-film transistor of claim 1; and
a pixel part that is connected with the thin-film transistor.

7. A method of manufacturing a thin-film transistor, comprising:
forming a gate electrode;
forming a gate insulating layer on the gate electrode;
forming a channel layer including oxide semiconductor on the gate insulating layer; and
forming a source electrode and a drain electrode on the channel layer, wherein
the gate insulating layer is formed by forming a first film containing silicon and one of nitrogen and oxygen, and performing plasma processing to introduce the other of nitrogen and oxygen into the first film, such that the gate insulating layer has a second film containing silicon, nitrogen, and oxygen as an upper surface thereof.

8. A method of manufacturing a thin-film transistor, comprising:
forming a channel layer including oxide semiconductor;
forming a gate insulating layer on the channel layer;
forming a gate electrode on the gate insulating layer; and
forming a source electrode and a drain electrode on the channel layer, wherein
the gate insulating layer is formed by forming a first film containing silicon and one of nitrogen and oxygen, and performing plasma processing to introduce the other of nitrogen and oxygen into the first film, such that the gate insulating layer has a second film containing silicon, nitrogen, and oxygen as a lower surface thereof.

9. The method of claim 7, wherein
as the first film, a silicon oxide film or a silicon nitride film is formed, and
as the second film, a silicon oxynitride film is formed, the silicon oxynitride film resulting from performing plasma nitridation processing on the silicon oxide film or performing plasma oxidation processing on the silicon nitride film.

10. The method of claim 8, wherein
as the first film, a silicon oxide film or a silicon nitride film is formed, and
as the second film, a silicon oxynitride film is formed, the silicon oxynitride film resulting from performing plasma nitridation processing on the silicon oxide film or performing plasma oxidation processing on the silicon nitride film.
